(19) United States
(12) Patent Application Publication
(10) Pub. No.: US 2018/0126466 A1
(43) Pub. Date: May 10, 2018

(54) MACHINING TOOL

(71) Applicant: GUEHRING KG, Albstadt (DE)

(72) Inventors: Stefan SATTEL, Strassberg (DE); Immo Garrn, Ertingen (DE); Manfred Schwenck, Albstadt (DE)

(73) Assignee: GUEHRING KG, Albstadt (DE)

(21) Appl. No.: 15/807,721

(22) Filed: Nov. 9, 2017

Related U.S. Application Data
(63) Continuation of application No. PCT/DE2016/000198, filed on May 10, 2016.

(30) Foreign Application Priority Data
May 12, 2015 (DE) 10 2015 208 742.5

(51) Int. Cl. B23B 51/02; C23C 16/02; C23C 16/27

(52) U.S. Cl. CPC B23B 51/02; C23C 16/0263; B23B 2228/10; B23B 2228/04; B23B 2226/31; C23C 16/27

(57) ABSTRACT

The present invention relates to a machining tool having a substrate surface made of a hard metal or a ceramic material, said substrate surface containing hard material particles on the basis of carbide and/or nitride and/or oxide that are embedded in a cobalt-containing binder matrix, and the substrate surface being smoothened. The substrate surface of the machining tool can be smoothened by way of a treatment with an ion beam that consists of monomer ions of at least one cation species, the cation species being mono-or poly-charged and being selected from the group consisting of: cations of the main group elements lithium, boron, aluminum, gallium, carbon, silicon, germanium, nitrogen, phosphorus and oxygen; and cations of the transition metals titanium, zirconium, vanadium, niobium, tantalum, chromium, molybdenum, tungsten, manganese, iron, cobalt, nickel and copper.

The present invention pertains to a machining tool according to the preamble of claim 1.

Various types of machining tools with a tool head, a tool shaft and a clamping section for being accommodated in a tool receptacle are known from the prior art.

In the region of their cutting edge, such tools feature functional areas that are adapted to the specific requirements of the materials to be machined.

The aforementioned tools are particularly realized in the form of drilling, milling, counterboring, turning, threading, contouring or reaming tools and may feature cutting bodies or guide rails as functional areas, wherein the cutting bodies may be realized, for example, in the form of indexable inserts and the guide rails may be realized, for example, in the form of support rails.

Tools of this type usually feature functional areas that provide the tool with a high wear resistance for machining highly abrasive materials.

DE 20 2005 021 817 U1 of the present applicant describes tool heads, which consist of a hard material with at least one functional layer that comprises a superhard material such as cubic boron nitride (CBN) or polycrystalline diamond (PCD).

Such a tool makes it possible to achieve long service lives with respect to the mechanical and thermal requirements of drilling, milling or reaming processes.

Methods for applying a polycrystalline film, particularly a polycrystalline film of diamond material, onto non-diamond substrates have also been known for quite some time. For example, U.S. Pat. No. 5,082,359 describes the application of a polycrystalline diamond film by means of chemical vapor deposition (CVD).

In the method described in this prior art document, a series of discrete nucleation points, which typically have the shape of craters, is produced on the surface of the functional area of a tool to be coated.

According to U.S. Pat. No. 5,082,359, these craters, which serve as nucleation sites for the subsequent diamond deposition, can be produced with a number of methods, for example by means of laser evaporation and chemical etching or plasma etching processes, in which a correspondingly patterned photoresist is used, or also by means of a focused ion beam (focused ion beam milling).

In U.S. Pat. No. 5,082,359, it is disclosed that craters with a spacing of less than 1 μm can be produced in the substrates with a focused ion beam of Ga+ with a kinetic energy of 25 KeV by focusing the Ga+ ion beam on a diameter of less than 0.1 μm, i.e. that nanobores can effectively be in produced in a workpiece with such a focused ion beam.

Typical materials used in the semiconductor industry such as germanium, silicon, gallium arsenide and polished wafers of monocrystalline silicon are cited as substrates in U.S. Pat. No. 5,082,359, wherein titanium, molybdenum, nickel, copper, tungsten, tantalum, steel, ceramic, silicon carbide, silicon nitride, silicon aluminum oxynitride, boron nitride, aluminum oxide, zinc sulfide, zinc selenide, tungsten carbide, graphite, silica glass, glass and sapphire are cited as other useful substrates.

The CVD is ultimately carried out due to the reaction of methane and hydrogen on a hot tungsten wire in a vacuum in order to deposit the carbon produced in high vacuum onto the crater-shaped irregularities produced on the substrate surface in its diamond modification.

It is furthermore known to provide the functional surfaces of tools with a diamond layer, wherein a CVD method is likewise used for this purpose.

Such a diamond coating method is described, for example, in WO 98/35071 A1. WO 2004/031437 A1 particularly describes the deposition of a polycrystalline diamond film on a hard metal substrate, which is made of tungsten carbide embedded in a cobalt matrix.

A hard metal typically contains sintered materials of hard material particles and a binder material, for example tungsten carbide grains, wherein these tungsten carbide grains form the hard materials and the cobalt-containing binder matrix serves as binder for the tungsten carbide grains and provides the layer with the required toughness for the tool.

Diamond-coated hard metal tools or cermet tools naturally have positive effects on the wearing protection of the tool, as well as its service life during continuous use.

Different methods for smoothing the surfaces of hard metal or cermet tools are known from the prior art. The surfaces may on the one hand be conventionally ground, for example with aluminous or diamond abrasives, and on the other hand smoothed by means of chemical-mechanical polishing methods (CMP), in which additional etching and/or polishing abrasives are used. Such a CMP method for producing an exact planarity of semiconductor surfaces is described, for example, in US 2012/0217587 A1.

Electropolishing methods, in which surface smoothing is achieved by means of a current flow and suitable electrolytes, are furthermore used in the semiconductor industry. Such methods are described, for example, in WO 97/07264 A1.

Other methods for producing a preferably perfect planarity in preparation for creating IC topographies of semiconductor surfaces are also described in US 2012/0217587 A1. According to US 2012/0217587 A1, the semiconductors may consist of the usual elementary semiconductors Si and Ge in monocrystalline, polycrystalline or amorphous form, as well as of semiconductor compounds such as, for example, silicon carbide, gallium arsenide, gallium phosphide, indium phosphide, indium arsenide and indium antimonide. Furthermore, alloyed semiconductor systems such as SiGe, GaAsP, AlInAs, AlGaAs, GalnAs, GaInP or GaInAsP can also be surface-treated.

After a corresponding preparation by variably filling depressions and, if so required, applying coatings with cover layers featuring the patterns required for creating the required topography at the desired locations, maximum planarity is according to US 2012/0217587 A1 initially produced with chemical-mechanical polishing methods and subsequently by irradiation with cluster ions with kinetic energies between 1 and 90 KeV. In this case, nano-dimensional cluster ions are produced of highly reactive gases and remove the desired surface layer to be planarized by means of etching such that highly planar surfaces are produced. According to US 2012/0217587 A1, the etching gases NF₃, CF₄, CₓF_{y} or CₘHₙF_{O} or halogenides such as HBr, HF, SF₆ or Cl₂ are used as gases for producing the cluster ions. In ionized form, these gases particularly react with and volatilize the Si in the cover layers in the form of volatile fluorides such as SiF₄ such that the irradiated layer is removed by etching, wherein the high planarity required for creating the topography can be achieved. According to US 2012/0217587 A1, auxiliary etching gases such as O₂, N₂ or NH₃ may be additionally admixed, if so required. Furthermore, it is also possible to use doping gases that allow the required doping implantations in the desired semiconductor. For example, B₂H₆, PH₃, AsH₃ or GeH₄ may be considered as doping gases.

The treatment of diamond-coated cutting tools with cluster gas ion beams for the purpose of smoothing the diamond layer is described in Japanese patent application JP 2010 036 297. In this case, a cluster gas consisting of pure argon or an Ar—O₂ mixture with an O₂ content of 34% is ionized and beamed on a CVD diamond layer in order to achieve a homogenous surface roughness and idiomorphic diamond layers. The average cluster size amounts to approximately 1000 atomic or molecular subunits. The accelerating voltages amount to 20 to 30 KV.

Devices for producing gas clusters, e.g. of CO₂, and generating ion beams thereof are described, for example, in JPH08120470 (A). According to this publication, for example, CO₂ gas from a pressurized reservoir is injected into a chamber with supersonic speed by a nozzle and expanded in an adiabatic fashion in order to form (electrically neutral) molecule clusters. The clusters are subsequently bombarded with electrons in an ionizer such that ion clusters are formed, which are then accelerated by means of electric fields and focused by means of magnetic fields. According to JPH08120470 (A), the CO₂ gas cluster ion beam can be used for ultra-precision grinding of solid object surfaces.

Ultimately, YAMADA et al. describe process technologies with cluster ion beams and elucidate the theoretical and practical background in Nucl. Instr. And Meth. in Phys. Res. B 206 (2003), pp. 820-829: “Cluster Ion Beam Process Technology.” YAMADA et al. particularly compare the effects of gas cluster ion beams with those of monomeric ion beams. According to the review article by YAMADA et al., the closest comparison with the bombardment of an object with cluster ion beams is the impact of a metallic asteroid with a diameter of approximately 30 m on earth's surface such as, for example, the meteorite impact that occurred in the northern part of Arizona approximately 50,000 years ago. The impact of this meteorite created a crater with a diameter of 1.2 km and the typical raised crater edge of ejected material. On a microscopic scale, similar craters are produced on solid object surfaces due to the impact of high-energy particles or heavy ions. YAMADA et al. discuss the impact of an Ar cluster ion on a gold surface: in this case, a microscopic crater with a diameter of approximately nm is created, i.e. a microscopic crater that is approximately 4×10¹⁰-times smaller than the aforementioned meteorite crater.

It is estimated that such cluster ion beams briefly cause temperatures of several ten thousand degrees and pressures in the gigapascal range in the target region.

In contrast to gas cluster ion irradiations, such effects do not occur during the irradiation of surfaces with monomeric ions as explained by YAMADA et al.

It should therefore be noted that the bombardment of solid object surfaces with cluster ions causes considerable damages in the structure of the irradiated substrate and fine surface polishing by means of cluster ions has to be associated with a plurality of microscopic craters in the treated substrate surface.

In the manufacture of high-performance cutting tools, however, a drastic structural change—of the type expected during the irradiation with cluster ions—is undesirable while smoothing the tool substrate surface, which is already finished with respect to its chemical composition and crystal lattice.

Based on the prior art according to the review article by YAMADA et al., the present invention therefore aims to make available highly smoothed tool surfaces, in which the disadvantageous structural changes of the prior art are at least largely prevented.

This objective is attained with the characteristics of claim 1.

The present invention particularly pertains to a machining tool with a substrate surface made of a hard metal or a ceramic material, wherein the substrate surface contains hard material particles on the basis of carbide and/or nitride and/or oxide, which are embedded in a cobalt-containing binder matrix, and the substrate surface is smoothed, wherein smoothing of the substrate surface of the machining tool can be achieved by means of a treatment with an ion beam of monomeric ions of at least one cation species, and wherein the cation species is mono-charged or poly-charged and selected from the group consisting of: cations of the main group elements lithium, boron, aluminum, gallium, carbon, silicon, germanium, nitrogen, phosphorus and oxygen; as well as cations of the transition metals titanium, zirconium, vanadium, niobium, tantalum, chromium, molybdenum, tungsten, manganese, iron, cobalt, nickel and copper.

In light of the prior art according to the initially discussed review article by YAMADA et al., it is surprising that a structure-preserving ultrafine polish and therefore smoothing of the surface roughness on machining tools can be achieved by means of an ion beam of monomeric ions according to the present invention.

A preferred embodiment of the present invention pertains to a tool, in which the hard material particles are selected from the group consisting of: the carbides, carbonitrides and nitrides of the non-radioactive metals of the IV., V., VI. and VII. subgroups of the periodic table of the elements and boron nitride, particularly cubic boron nitride; as well as oxidic hard materials, particularly aluminum oxide and chromium oxide; as well as, in particular, titanium carbide, titanium nitride, titanium carbonitride; vanadium carbide, niobium carbide, tantalum carbide; chromium carbide, molybdenum carbide, tungsten carbide; manganese carbide, rhenium carbide; as well as mixtures and mixed phases thereof.

In addition to cobalt, the binder matrix may advantageously also contain aluminum, chromium, molybdenum and/or nickel such that the toughness can be precisely adjusted.

Another preferred embodiment of the present invention pertains to a machining tool, in which the ceramic material is a sintered material of the above-listed hard material particles in a binder matrix that in addition to cobalt also contains aluminum, chromium, molybdenum and/or nickel.

It is preferred to use a sintered hard metal of carbide or carbonitride as ceramic material.

The inventive tools may be realized in the form of rotating or stationary tools, particularly drilling, milling, counterboring, turning, threading, contouring or reaming tools. The complete assortment of tools with the inventive surface properties is thereby made available to users.

The inventive tools may conventionally have a monolithic or modular design.

Typical tools may feature at least one cutting body, particularly an insert, preferably an indexable insert, on a support body and/or at least one guide rail, particularly a support rail.

It is particularly advantageous that the tool is made of a high-speed steel, particularly a steel with the DIN key to steel 1.3343, 1.3243, 1.3344 or 1.3247. A broad assortment of high-quality tools with very finely polished surfaces is thereby made available to users.

Even machining tools with at least one functional area that is diamond-coated, particularly by means of CVD, can be processed with the monomeric ion beams in such a way that a uniform idiomorphic diamond layer is obtained. In crystallographic terms, thickness fluctuations of the diamond layer (see JP 2010 036 247) caused by the growth of the cubic diamond crystals in different privileged directions, e.g. [111] or [001], are thereby essentially eliminated with the ion beam treatment such that inventive tools, for example, twist drills with diameters up to 6 mm, can be technically realized with a manufacturing accuracy up to ±1000 nm. Regardless of the location, the inventive machining tool therefore also has the same thickness over the entire functional area, e.g. of a drill, such that much more exact and uniform drill holes can be realized in the workpiece in this case.

In any event, drilling tools according to the present invention, for example, reach a higher classification, i.e. stricter dimensional tolerances, in the twist drill manufacturing accuracy according to DIN ISO 286, Part 2. Twist drills of the applicant in the diameter range between 0.38 mm and 120.00 mm are typically manufactured with a manufacturing accuracy of ISO h8. If the tools according to the present invention are treated by means of ion beams, the same tools can be manufactured with a manufacturing accuracy of ISO h7. This means that the diameter deviation, for example, of a 50 mm twist drill with a manufacturing accuracy of ISO h8 amounts to ±39 μm whereas the diameter deviation of the inventive 50 mm twist drills with a manufacturing accuracy of ISO h7 merely amounts to ±25 μm.

Other advantages and characteristics of the present invention can be gathered from the description of exemplary embodiments.

### EXAMPLE

Hard metal drilling tools made of a hard metal with 10% Co by mass and an average WC grain size of 0.6 μm (Gühring brand name DK460UF) were in accordance with the invention irradiated with an ion stream of essentially monomeric nitrogen ions for 1.5 h, wherein the ion stream was generated with a voltage of 30 kV at a plasma current of 3 mA and a nitrogen pressure of 1×10⁻⁵ mbar. A commercially available ion generator (ion generator “Hardion” of the firm Quertech, Caen) was used for generating the ion beam.

During the ion beam treatment, the tool, which in the described example consists of a twist drill with a diameter of 6.00 mm, was subjected to the nitrogen ion beam at an angle of incidence of 0°, i.e. in the longitudinal direction from the drill tip, while rotating about its longitudinal axis. Prior to the treatment, the twist drill complied with manufacturing accuracy ISO h8. After the treatment, measurements according to DIN ISO 286, Part 2, showed a manufacturing accuracy of ISO h7 and partly better.

1. A machining tool with a substrate surface made of a hard metal or a ceramic material, wherein:
the substrate surface contains hard material particles on the basis of carbide and/or nitride and/or oxide, which are embedded in a cobalt-containing binder matrix, and the substrate surface is smoothed, and
smoothing of the substrate surface of the machining tool can be achieved by means of a treatment with an ion beam of monomeric ions of at least one cation species, wherein the cation species is mono-charged or poly-charged and selected from the group consisting of: cations of the main group elements lithium, boron, aluminum, gallium, carbon, silicon, germnanium, nitrogen, phosphorus and oxygen; as well as cations of the transition metals titanium, zirconium, vanadium, niobium, tantalum, chromium, molybdenum, tungsten, manganese, iron, cobalt, nickel and copper.

2. The tool according to claim 1, wherein the hard particles are selected from the group consisting of: the carbides, carbonitrides and nitrides of the non-radioactive metals of the IV., V., VI. and VII. subgroups of the periodic table of the elements and boron nitride, oxidic hard materials, titanium carbide, titanium nitride, titanium carbonitride, vanadium carbide, niobium carbide, tantalum carbide, chromium carbide, molybdenum carbide, tungsten carbide, manganese carbide, and rhenium carbide, as well as mixtures and mixed phases thereof.

3. The tool according to claim 1, wherein the binder matrix also contains aluminum, chromium, molybdenum and/or nickel.

4. The tool according to claim 2, wherein the binder matrix also contains aluminum, chromium, molybdenum and/or nickel.

5. The tool according to claim 4, wherein the ceramic material is a sintered hard metal of carbide or carbonitride.

6. The tool according to claim 1, wherein the tool is a rotating tool or a stationary tool.

7. The tool according to claim 1, wherein the tool has a monolithic or modular design.

8. The tool according to claim 1, wherein at least one cutting body is provided on a support body and/or at least one guide rail is provided.

9. The tool according to claim 1, wherein the substrate is made of a high-speed tool steel.

10. The tool according to claim 1, wherein the tool comprises at least one functional area that is diamond-coated.

11. The tool according to claim 2, wherein the hard particles are selected from the group consisting of cubic boron nitride, aluminum oxide and chromium oxide.

12. The tool according to claim 6, wherein the tool is a drilling, milling, counterboring, turning, threading, contouring or reaming tool.

13. The tool according to claim 8, wherein the cutting body is an insert.

14. The tool according to claim 13, wherein the cutting body is an indexable insert.

15. The tool according to claim 8, wherein the guide rail is a support rail.

16. The tool according to claim 1, wherein the substrate is made of a steel with the DIN key to steel 1.3343, 1.3243, 1.3344 or 1.3247.

17. The tool according to claim 1, wherein the tool comprises at least one functional area that is diamond-coated by means of
